(19) United States
(12) Patent Application Publication
(10) Pub. No.: US 2025/0105201 A1
(43) Pub. Date: Mar. 27, 2025

(54) SEMICONDUCTOR PACKAGE INCLUDING A BONDING WIRE

(71) Applicant: SAMSUNG ELECTRONICS CO., LTD., SUWON-SI (KR)

(72) Inventor: Younghun KIM, Suwon-si (KR)

(21) Appl. No.: 18/741,372

(22) Filed: Jun. 12, 2024

(30) Foreign Application Priority Data
Sep. 22, 2023 (KR) 10-2023-0127419

(51) Int. Cl. H01L 23/00; H01L 23/31; H01L 23/498

(52) U.S. Cl. CPC H01L 24/48; H01L 24/32; H01L 24/33; H01L 24/73; H01L 23/3107; H01L 23/49822; H01L 2224/26155; H01L 2224/32225; H01L 2224/33183; H01L 2224/48091; H01L 2224/48227; H01L 2224/73215

(57) ABSTRACT

A semiconductor package includes a package substrate including a package substrate comprising a base layer and a connection pad disposed on an upper surface of the base layer; a semiconductor chip disposed on the package substrate and the semiconductor chip comprises a semiconductor substrate and a bonding pad disposed on an upper surface of the semiconductor substrate; a bonding wire in contact with the connection pad and the bonding pad; a first dam structure disposed on the package substrate and arranged between the connection pad and the bonding pad; a non-conductive filler disposed on the package substrate surrounding the first dam structure and the bonding wire; and a mold layer disposed on the package substrate covering a portion of an upper surface of the package substrate and surrounding the semiconductor chip and the non-conductive filler.

### CROSS-REFERENCE TO RELATED APPLICATION

This application claims priority under 35 U.S.C. §119 to Korean Patent Application No. 10-2023-0127419, filed on Sep. 22, 2023, in the Korean Intellectual Property Office, the disclosure of which is incorporated by reference herein in its entirety.

### 1. TECHNICAL FIELD

The inventive concept relates to a semiconductor package. More particularly, the inventive concept relates to a semiconductor package including a bonding wire.

### 2. DESCRIPTION OF THE RELATED ART

As electronic devices become more compact and multi-functional, there is a need for a highly integrated semiconductor chip.

After a bonding wire connecting a semiconductor chip and a substrate is formed, a sweep phenomenon occurs in which the bonding wire bends or drops down due to flow of molding material during a molding process. When a thin wire or a long wire is used to mount a miniaturized semiconductor chip on a substrate, this problem may become more severe.

### SUMMARY

The inventive concept provides a semiconductor package having improved reliability. According to an aspect of the inventive concept, there is provided a semiconductor package. The semiconductor package includes a package substrate comprising a base layer and a connection pad disposed on an upper surface of the base layer; a semiconductor chip disposed on the package substrate and the semiconductor chip comprises a semiconductor substrate and a bonding pad disposed on an upper surface of the semiconductor substrate; a bonding wire in contact with the connection pad and the bonding pad; a first dam structure disposed on the package substrate and arranged between the connection pad and the bonding pad; a non-conductive filler disposed on the package substrate surrounding the first dam structure and the bonding wire; and a mold layer disposed on the package substrate covering a portion of an upper surface of the package substrate and surrounding the semiconductor chip and the non-conductive filler.

According to another aspect of the inventive concept, there is provided a semiconductor package. The semiconductor package includes a package substrate comprising a base layer and a plurality of connection pads disposed on an upper surface of the base layer; a semiconductor chip disposed on the package substrate and spaced apart from the plurality of connection pads, the semiconductor chip comprises a semiconductor substrate and a plurality of bonding pads disposed on an upper surface of the semiconductor substrate; a heat dissipation structure spaced apart from the plurality of bonding pads and disposed on an upper surface of the semiconductor chip; a plurality of bonding wires electrically connecting the plurality of connection pads to the plurality of bonding pads, respectively; a non-conductive filler at least partially surrounding the plurality of bonding wires, filling a lower space of the plurality of bonding wires, and covering a side wall of the heat dissipation structure; and a mold layer disposed on the package substrate surrounding the non-conductive filler, the heat dissipation structure, and the semiconductor chip.

According to another aspect of the inventive concept, there is provided a semiconductor package. The semiconductor package includes a package substrate comprising a base layer and a plurality of connection pads disposed on an upper surface of the base layer; a semiconductor chip at least partially surrounded by the plurality of connection pads, on the package substrate, the semiconductor chip comprises a semiconductor substrate and a plurality of bonding pads arranged on an upper surface of the semiconductor substrate along a perimeter of the semiconductor chip; a first dam structure spaced apart from the semiconductor chip, on the package substrate, and extending between the plurality of connection pads and the semiconductor chip along the perimeter of the semiconductor chip; a second dam structure disposed on the semiconductor chip and covering a portion of an upper surface of the semiconductor chip and exposing the plurality of bonding pads; a plurality of bonding wires electrically connecting the plurality of connection pads to the plurality of bonding pads; a non-conductive filler disposed on the package substrate and at least partially surrounding the plurality of bonding wires and the first dam structure and covering at least a portion of a side wall of the second dam structure; and a mold layer disposed on the package substrate covering the non-conductive filler and the second dam structure.

### BRIEF DESCRIPTION OF THE DRAWINGS

Embodiments will be more clearly understood from the following detailed description taken in conjunction with the accompanying drawings in which:

FIG. 1A is a plan view of a semiconductor package according to embodiments;

FIG. 1B is a cross-sectional view of the semiconductor package taken along line X1-X1′ of FIG. 1;

FIG. 2 is a cross-sectional view of a semiconductor package according to some embodiments, and is a portion corresponding to the cross-sectional view taken along line X1-X1′ of FIG. 1;

FIG. 3 is a cross-sectional view of a semiconductor package according to some embodiments, and is a portion corresponding to the cross-sectional view taken along line X1-X1′ of FIG. 1;

FIG. 4A is a plan view of a semiconductor package according to some embodiments;

FIG. 4B is a cross-sectional view of the semiconductor package taken along line X2-X2′ of FIG. 4A;

FIG. 5A is a plan view of a semiconductor package according to some embodiments;

FIG. 5B is a cross-sectional view of the semiconductor package taken along line X3-X3′ of FIG. 5A;

FIG. 6 is a flow chart for describing a method of manufacturing a semiconductor package, according to embodiments; and

FIGS. 7A, 7B, 7C, 7D and 7E are cross-sectional views illustrating a method of manufacturing a semiconductor package, according to embodiments.

### DETAILED DESCRIPTION OF THE EMBODIMENTS

Hereinafter, embodiments of the inventive concept will be described in detail with reference to the accompanying drawings. In the drawings, like numerals may indicate like components throughout the description.

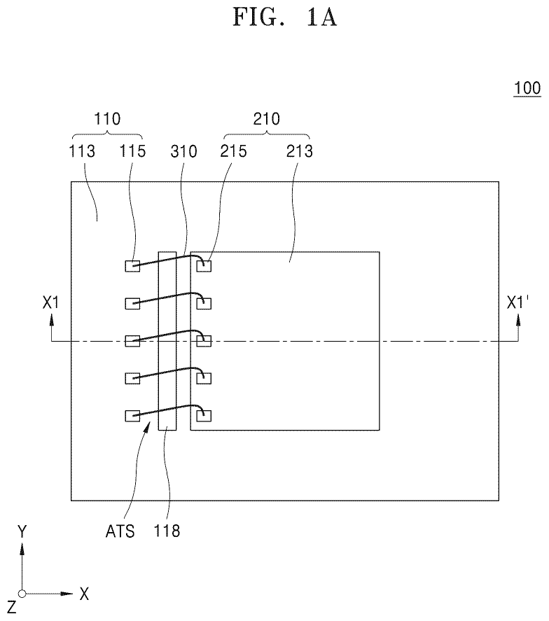

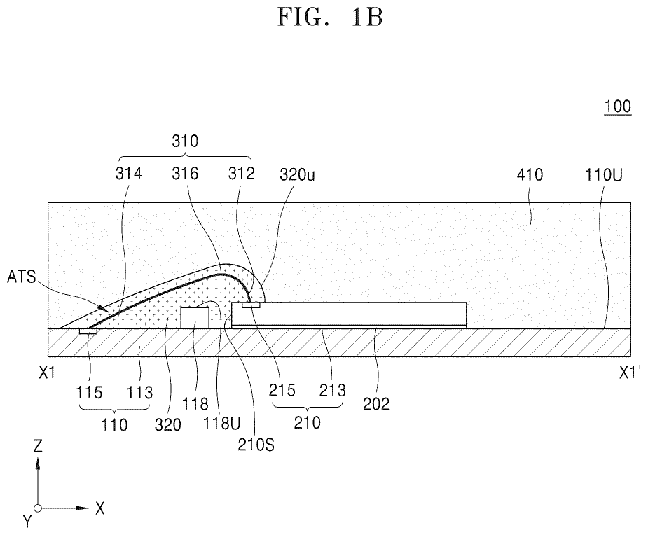

FIG. 1A is a plan view of a semiconductor package 100 according to embodiments. FIG. 1B is a cross-sectional view of the semiconductor package 100 taken along line X1-X1′ of FIG. 1.

Referring to FIGS. 1A and 1B, the semiconductor package 100 may include the a package substrate 110, a semiconductor chip 210 mounted on the package substrate 110, a first dam structure 118 arranged on one side of the semiconductor chip 210, a plurality of bonding wires 310 for connecting the package substrate 110 with the semiconductor chip 210, a non-conductive filler 320 disposed on the package substrate 110 at least partially surrounding the plurality of bonding wires 310 and covering the first dam structure 118, and a mold layer 410 disposed on the package substrate 110 at least partially covering the non-conductive filler 320 and the semiconductor chip 210.

According to embodiments, the semiconductor chip 210 may be mounted on the package substrate 110. FIGS. 1A and 1B illustrate a case where one semiconductor chip 210 is mounted on the package substrate 110, but the number of semiconductor chips 210 is not necessarily limited thereto. For example, a plurality of semiconductor chips 210 may be mounted on the package substrate 110.

According to embodiments, the package substrate 110 may include, as a support substrate and a mounting substrate, a base layer 113 and a plurality of connection pads 115 disposed on an upper surface of the base layer 113. For example, an upper surface of the connection pads 115 may be provided on an upper surface 110U of the package substrate 110.

In some embodiments, the plurality of connection pads 115 may be buried in the base layer 113, and the upper surfaces of the plurality of connection pads 115 may be coplanar with an upper surface of the base layer 113. In some embodiments, the plurality of connection pads 115 may be disposed on an upper surface of the base layer 113, protruding from the upper surface of the base layer 113 in a Z direction.

The plurality of connection pads 115 may be spaced apart from the semiconductor chip 210 and may be arranged along at least a portion of a perimeter of the semiconductor chip 210. For example, as shown in FIG. 1A, the semiconductor chip 210 may have a quadrangular planar shape, and the plurality of connection pads 115 may be arranged along one of four sides of an outer perimeter of the semiconductor chip 210. The plurality of connection pads 115 may be arranged apart from each other in a Y direction.

The package substrate 110 may include a solder resist layer that covers an upper surface of the base layer 113. At least a portion of the plurality of connection pads 115 may be exposed to the upper surface 110U of the package substrate 110 without being covered by the solder resist layer.

The base layer 113 may include at least one material selected from among a phenol resin, an epoxy resin, and polyimide. For example, the base layer 113 may include at least one material selected from flame retardant 4 (FR4), tetrafunctional epoxy, polyphenylene ether, epoxy/polyphenylene oxide, bismaleimide triazine (BT), Thermount, cyanate ester, polyimide, and liquid crystal polymer.

The plurality of connection pads 115 may include electrolytically deposited (ED) copper foil, rolled-annealed (RA) copper foil, stainless steel foil, aluminum foil, ultra-thin copper foil, sputtered copper, a copper alloy, etc., but are not necessarily limited to the aforementioned examples.

The package substrate 110 may include an internal wiring connected to the plurality of connection pads 115. The internal wiring may be electrically connected to the semiconductor chip 210 via the plurality of connection pads 115, the plurality of bonding wires 310, and a plurality of bonding pads 215 described below.

The package substrate 110 may be a printed circuit board (PCB), a wafer substrate, a ceramic substrate, a glass substrate, or an interposer substrate. In some embodiments, the package substrate 110 may be a double-sided PCB or a multi-layer PCB. When the package substrate 110 is a multi-layer PCB, a wiring layer may be disposed on a lower surface and upper surface 110U of the package substrate 110 and may be arranged in the package substrate 110.

The semiconductor chip 210 may be attached onto the upper surface 110U of the package substrate 110 via a die adhesive film 202 arranged between the semiconductor chip 210 and the package substrate 110. The die adhesive film 202 may include an inorganic adhesive or a polymer adhesive. The polymer adhesive may include, for example, a thermosetting polymer or a thermoplastic polymer. The thermosetting polymer has a three-dimensional cross-link structure after a monomer is heat molded, and might not be softened when reheated. In contrast, the thermoplastic polymer exhibits plasticity when heated, and may have a linear polymer structure. In some embodiments, the die adhesive film 202 may be of a hybrid type that is a mixture of the thermosetting polymer and the thermoplastic polymer.

According to embodiments, the semiconductor chip 210 may include a semiconductor substrate 213 and the plurality of bonding pads 215 disposed on an upper surface of the semiconductor substrate 213. For example, an upper surface of the plurality of bonding pads 215 may be provided on an upper surface of the semiconductor chip 210.

In some embodiments, the semiconductor substrate 213 may include a semiconductor element, such as silicon (Si) and germanium (Ge), or a compound semiconductor, such as silicon carbide (SiC), gallium arsenide (GaAs), indium arsenide (InAs), and indium phosphide (InP). In some embodiments, the semiconductor substrate 213 may have a silicon on insulator (SOI) structure. The semiconductor substrate 213 may include a conductive region, for example, a well doped with impurities. The semiconductor substrate 213 may have various device isolation structures, such as a shallow trench isolation (STI) structure. The semiconductor substrate 213 may have an active surface and an inactive surface opposite to the active surface.

In some embodiments, the semiconductor chip 210 may be mounted on the package substrate 110 such that the active surface of the semiconductor substrate 213 faces upward, that is, in a direction towards the mold layer 410 and opposite to the upper surface 110U of the package substrate 110. The inactive surface of the semiconductor substrate 213 may be arranged to face downward, that is, towards the upper surface 110U of the package substrate 110.

Various types of individual devices may be formed on the active surface of the semiconductor substrate 213. The individual devices may include various microelectronic devices, for example, a metal-oxide-semiconductor field effect transistor (MOSFET), such as a complementary metal-insulator-semiconductor (CMOS) transistor, an image sensor such as system large scale integration (LSI) and a CMOS imaging sensor (CIS), a micro-electro-mechanical system (MEMS), an active device, a passive device, etc. The individual devices may be electrically connected to the conductive region of the semiconductor substrate 213. The individual devices may be electrically isolated from other neighboring individual devices, respectively, due to an insulating film.

The semiconductor chip 210 may be a memory semiconductor chip. In some embodiments, the memory semiconductor chip may be a non-volatile memory device, such as flash memory, phase-change random access memory (PRAM), magnetoresistive random access memory (MRAM), ferroelectric random access memory (FeRAM), or resistive random access memory (RRAM). The flash memory may be, for example, V-NAND flash memory. In some embodiments, the memory semiconductor chip may be a volatile memory semiconductor chip, such as dynamic random access memory (DRAM) or static random access memory (SRAM).

In some embodiments, the semiconductor chip 210 may be a logic chip. The logic chip may be implemented as, for example, a microprocessor, a graphics processor, a signal processor, a network processor, a chipset, an audio codec, a video codec, an application processor, a system on chip, etc., but is not necessarily limited thereto.

The plurality of bonding pads 215 may be buried in the semiconductor substrate 213, and upper surfaces of the plurality of bonding pads 215 and an upper surface of the semiconductor substrate 213 may be coplanar with each other. In some embodiments, the plurality of bonding pads 215 may be disposed on the active surface of the semiconductor substrate 213 and may be exposed through an upper surface of the semiconductor chip 210. In some embodiments. For example, the plurality of bonding pads 215 may be disposed on an upper surface of the semiconductor substrate 213 and may protrude from the upper surface of the semiconductor substrate 213 in the Z direction.

In some embodiments, a passivation layer may be formed on the semiconductor substrate 213 to protect other structures in the individual devices and other structures within the semiconductor substrate 213 from external shock or moisture. The passivation layer may expose at least a portion of an upper surface of each of the plurality of bonding pads 215.

The plurality of bonding pads 215 may extend along at least a portion of a perimeter of the semiconductor chip 210. For example, the plurality of bonding pads 215 may be disposed on a portion of a perimeter of the semiconductor chip 210, the portion being adjacent to the plurality of connection pads 115, and may be arranged parallel to the plurality of connection pads 115. For example, the plurality of bonding pads 215 may be arranged apart from each other on one side of the semiconductor chip 210 in the Y direction.

According to embodiments, the first dam structure 118 may be disposed on the upper surface 110U of the package substrate 110 and may protrude from the upper surface 110U of the package substrate 110. According to embodiments, in a plan view, the first dam structure 118 may be arranged between the plurality of connection pads 115 and the plurality of bonding pads 215. For example, in a plan view, the first dam structure 118 may be spaced apart from the plurality of connection pads 115 and the plurality of bonding pads 215. The first dam structure 118 may be spaced apart from a side wall 210S of the semiconductor chip 210 and may extend along at least a portion of a perimeter of the semiconductor chip 210. For example, the first dam structure 118 may extend along the arrangement direction of the plurality of connection pads 115 or the plurality of bonding pads 215. The first dam structure 118 may be spaced apart from the side wall 210S of the semiconductor chip 210 and prevent mounting defects from errors in a process of mounting the semiconductor chip 210 on the package substrate 110. Additionally, it may prevent a non-conductive paste (NCP) forming the non-conductive filler 320 from dispersing when the NCP is applied, so that the non-conductive filler 320 may easily surround the uppermost portions of the plurality of bonding wires 310.

For example, the plurality of connection pads 115 and the plurality of bonding pads 215 may be arranged parallel to each other in the Y direction of the semiconductor chip 210, and the first dam structure 118 may extend between the plurality of connection pads 115 and the plurality of bonding pads 215 in the Y direction. For example, in a plan view, the first dam structure 118 may have a rod shape extending along one side wall 210S of the semiconductor chip 210.

In some embodiments, the first dam structure 118 may be formed by the same process as the base layer 113 of the package substrate 110, and thus, may form an integrated structure with the base layer 113. For example, the first dam structure 118 may include the same material as that of the base layer 113. In some embodiments, the first dam structure 118 may be attached onto the upper surface 110U of the package substrate 110 via a die adhesive film arranged between the first dam structure 118 and the package substrate 110. For example, the first dam structure 118 may include bulk silicon (Si) but is not necessarily limited to the aforementioned example.

According to embodiments, each of the plurality of bonding wires 310 may connect one selected from among the plurality of connection pads 115 with one selected from among the plurality of bonding pads 215. According to embodiments, each of the plurality of bonding wires 310 may have an arc shape with a curvature. For example, the plurality of bonding wires 310 may form an arch tunnel structure ATS, and the first dam structure 118 may be disposed under the plurality of bonding wires 310 to pass the arch tunnel structure ATS. For example, one end of the arch tunnel structure ATS extending in an X direction may be connected to the plurality of connection pads 115, and the other end may be connected to the plurality of bonding pads 215. For example, the arch tunnel structure ATS may vertically overlap an edge portion of the semiconductor chip 210 and may extend along a portion of a perimeter of the semiconductor chip 210.

According to embodiments, each of the plurality of bonding wires 310 may include a first portion 312 which is in contact with and connected to each bonding pad 215, a second portion 314 which is in contact with and connected to each connection pad 115, and a third portion 316 between the first portion 312 and the second portion 314. The third portion 316 having a peak with a maximum vertical level. In some embodiments, each of the plurality of bonding wires 310 may have a downward slope with respect to the peak of the third portion 316 and may extend toward both ends, for example, the first portion 312 and the second portion 314. The term “vertical level” used herein refers to a distance in a vertical direction (Z direction or −Z direction) from the upper surface 110U of the package substrate 110.

The upper surfaces of the plurality of connection pads 115 may be arranged at a lower vertical level than the plurality of bonding pads 215. The length of the first portion 312 of each of the plurality of bonding wires 310 may be less than the length of the second portion 314.

The plurality of bonding wires 310 may include at least one selected from gold (Au), silver (Ag), copper (Cu), and aluminum (Al).

According to embodiments, the non-conductive filler 320 may be disposed on the package substrate 110 covering the arch tunnel structure ATS, and may fill a lower space of the arch tunnel structure ATS. The non-conductive filler 320 may fix and protect the plurality of bonding wires 310 from being damaged by external factors in a subsequent process. Accordingly, the non-conductive filler 320 may prevent the plurality of bonding wires 310 from being separated from the plurality of connection pads 115 and/or the plurality of bonding pads 215, and may prevent short circuits from occurring between adjacent bonding wires 310 due to the plurality of bonding wires 310 being swept.

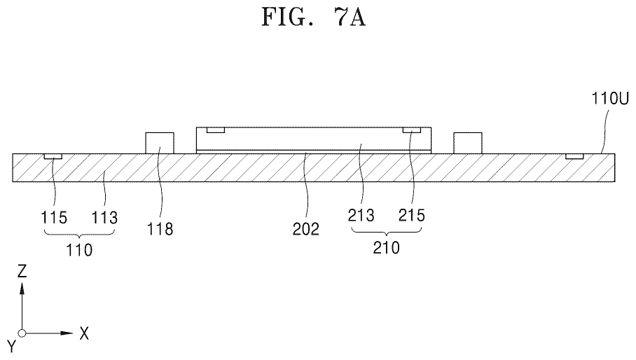

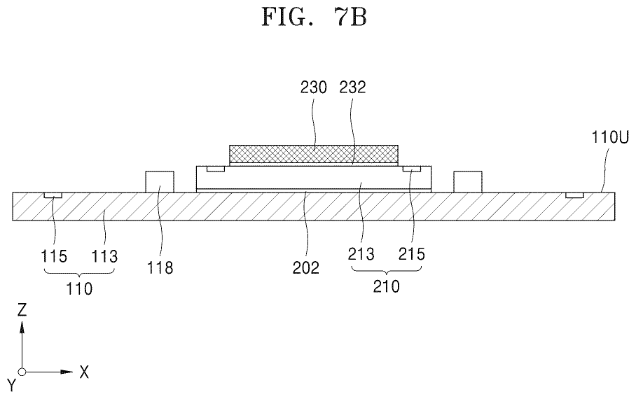

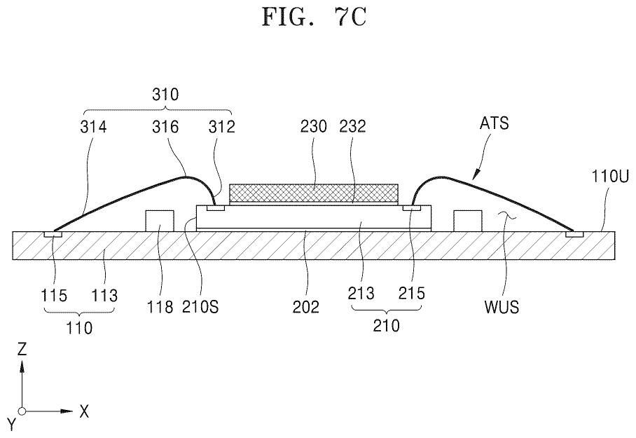

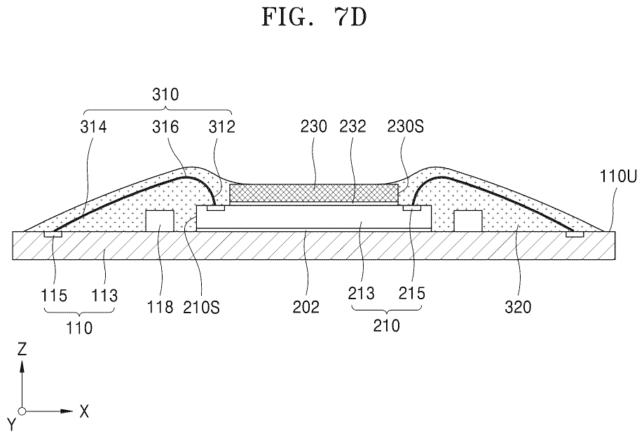

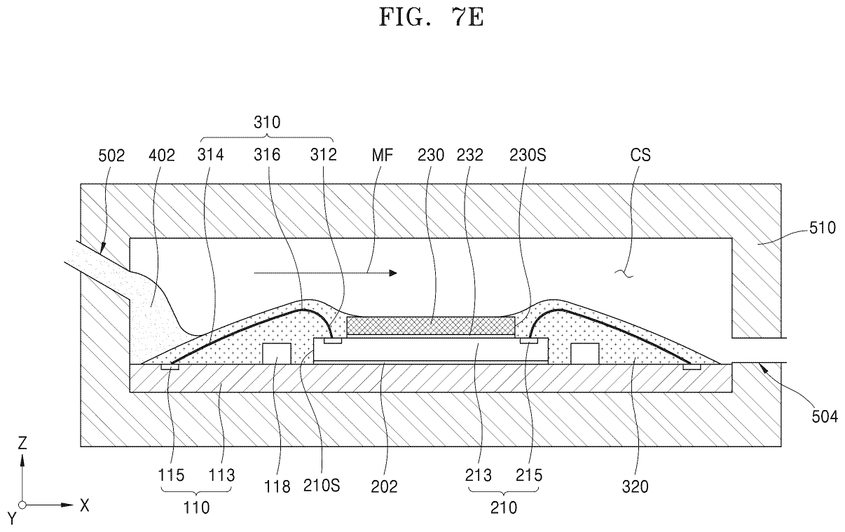

In some embodiments, the non-conductive filler 320 may fill, as a lower space of the arch tunnel structure ATS, a wire lower space WUS (see FIG. 7C) defined by the plurality of bonding wires 310, a portion of the upper surface 110U of the package substrate 110, an upper surface and side wall of the first dam structure 118, a portion of an upper surface of the semiconductor chip 210, and the side wall 210S of the semiconductor chip 210.

The non-conductive filler 320 may surround the plurality of bonding wires 310. The non-conductive filler 320 may cover at least a portion of upper surfaces of the plurality of connection pads 115, cover at least a portion of upper surfaces of the plurality of bonding pads 215, and cover at least a portion of the side wall 210S of the semiconductor chip 210 and a portion of an upper surface of the semiconductor chip 210. In addition, the non-conductive filler 320 may cover the first dam structure 118. For example, the non-conductive filler 320 may cover an upper surface 118U of the first dam structure 118 and at least a portion of both side walls of the first dam structure 118. Additionally, the non-conductive filler 320 may cover a portion arranged between the first dam structure 118 and the side wall 210S of the semiconductor chip 210. However, it may not be necessarily limited thereto. For example, in some embodiments, a space between the first dam structure 118 and the side wall 210S of the semiconductor chip 210 might not be filled with the non-conductive filler 320.

The arch tunnel structure ATS may extend along one side of the semiconductor chip 210 having a quadrangular planar shape as shown in FIGS. 1A and 1B, and the non-conductive filler 320 may vertically overlap an edge portion of the semiconductor chip 210.

An upper surface 320U of the non-conductive filler 320 may have a profile corresponding to an upper surface of the arch tunnel structure ATS in the X direction. IA portion of the upper surface 320U of the non-conductive filler 320, the portion vertically overlapping the third portion third portion 316 of the plurality of bonding wires 310, may have a curvature. For example, the upper surface 320U of the non-conductive filler 320 may have a curvature corresponding to a curvature of each of the plurality of bonding wires 310. The upper surface 320U of the non-conductive filler 320 may have a peak with a maximum vertical level, and may have a downward slope with respect to the peak and extend in the X direction. In The non-conductive filler 320 may cover a peak of the third portion 316 of the plurality of bonding wires 310. For example, a first peak of upper surfaces of the plurality of bonding wires 310, the first peak being a maximum vertical level, may be arranged at a higher vertical level than the peak of the third portion 316 of the plurality of bonding wires 310. In The width of the non-conductive filler 320 in the X direction may be greater than the width of each of the plurality of bonding wires 310 in the X direction such that the non-conductive filler 320 covers the arch tunnel structure ATS.

According to embodiments, the mold layer 410 may be disposed on the package substrate 110 to cover an upper surface 110U of the package substrate 110 and may surround the non-conductive filler 320 and the semiconductor chip 210. The mold layer 410 may serve to protect the semiconductor chip 210 from external influences, such as contamination and shock.

The non-conductive filler 320 may be formed from an NCP including silica filler, an acrylic resin, and an epoxy resin. For example, the non-conductive filler 320 may include a first silica filler.

In some embodiments, the mold layer 410 may include an epoxy molding compound (EMC). For example, the mold layer 410 may be formed from a granule including silica filler, an epoxy resin, and an additive, such as a crosslinking agent, a curing accelerator, and an ion catcher. For example, the mold layer 410 may include a second silica filler.

The size of the first silica filler of the non-conductive filler 320 may be less than the size of the second silica filler of the mold layer 410. The size of the first silica filler may be about 0.5 μm to about 3 μm, and the size of the second silica filler may be about 15 μm to about 25 μm, but the sizes are not necessarily limited to the aforementioned ranges.

The semiconductor package 100 according to embodiments may include the first dam structure 118 disposed under the plurality of bonding wires 310, and the non-conductive filler 320. The non-conductive filler 320 may be formed by applying an NCP and then curing the NCP. When applying the NCC to the plurality of bonding wires 310 to form the non-conductive filler 320, the high fluidity of the NCP, attributed to its relatively low viscosity, poses a challenge. Without a first dam structure 118, there is a risk of the NCP flowing along the upper surface 110U of the package substrate 110, leaving the plurality of bonding wires 310 incompletely surrounded, particularly at the peaks of each bonding wire 310. Thus, the first dam structure 118 partially filling a lower space of the plurality of bonding wires 310 allows more stable enclosure of the plurality of bonding wires 310 by the NCP through interfacial tension between the NCP and the surface of the first dam structure 118, and the interfacial tension between the NCP and the plurality of bonding wires 310. The interfacial tension as used herein may be referred to as surface energy.

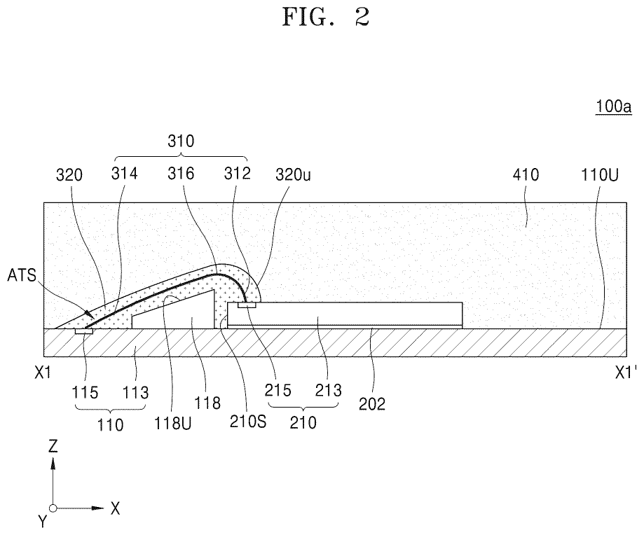

FIG. 2 is a cross-sectional view of a semiconductor package 100a according to some embodiments and is a portion corresponding to the cross-sectional view taken along line X1-X1′ of FIG. 1. A difference between FIG. 2 and FIG. 1B is whether the upper surface 118U of the first dam structure 118 has a downward slope. In FIG. 2, reference numerals that are the same as those in FIGS. 1A and 1B denote elements that are the same as those in FIGS. 1A and 1B. Therefore, to the extent that details are not described, it may be assumed that the elements are at least similar to corresponding elements described elsewhere in the specification.

Referring to FIG. 2, the upper surface 118U of the first dam structure 118 of FIG. 1B is parallel to a package substrate 110, whereas the upper surface 118U of the first dam structure 118 of FIG. 2 may be inclined with respect to a plane parallel to the package substrate 110.

According to embodiments, the upper surface 118U of the first dam structure 118 may have a vertical level that increases toward the semiconductor chip 210. FIG. 2 illustrates a vertical cross-section in the X direction which is a horizontal direction perpendicular to an extension direction (for example, Y direction) of the first dam structure 118. Both side walls of the first dam structure 118 in the X direction may have different lengths from each other in the Z direction. For example, the length of a first side wall that faces the side wall 210S of the semiconductor chip 210 among both side walls of the first dam structure 118 in the Z direction may be greater than the length of a second side wall that is opposite to the first side wall in the Z direction. In some embodiments, the upper surface 118U of the first dam structure 118 may extend with a downward slope in a direction away from the side wall 210S of the semiconductor chip 210, for example, along an opposite of the X direction.

In the semiconductor package 110a according to embodiments, the upper surface 118U of the first dam structure 118 may have an inclined profile (for example, a downward slope) which is similar to or substantially the same as that of a portion of the plurality of bonding wires 310, the portion vertically overlapping the first dam structure 118. For example, the second portion 314 of the plurality of bonding wires 310 may extend with a downward slope along the opposite of X direction, away from a peak of the third portion 316. The first dam structure 118 may vertically overlap the second portion 314, and the upper surface 118U of the first dam structure 118 may extend with a downward slope in a direction away from the side wall 210S. The upper surface 118U of the first dam structure 118 may have a downward slope, and the plurality of bonding wires 310 extend, and thus, a significant increase in distance between the upper surface 118U of the first dam structure 118 and the plurality of bonding wires 310 may be prevented. Accordingly, the non-conductive filler 320 may be formed to have a relatively constant thickness on the upper surface 118U of the first dam structure 118. For example, in a process of applying an NCP for forming the non-conductive filler 320, the NCP may be prevented from spreading out of a lower space of the plurality of bonding wires 310 via interfacial tension at a portion in contact with the upper surface 118U of the first dam structure 118 and the plurality of bonding wires 310.

FIG. 2 illustrates that the second portion 314 of the plurality of bonding wires 310 has an arc shape, and the upper surface 118U of the first dam structure 118 has a planar shape, but the inventive concept is not necessarily limited thereto. For example, the second portion 314 of the plurality of bonding wires 310 may have a shape similar to a straight line with a low curvature. For example, the upper surface 118U of the first dam structure 118 may have a curved surface.

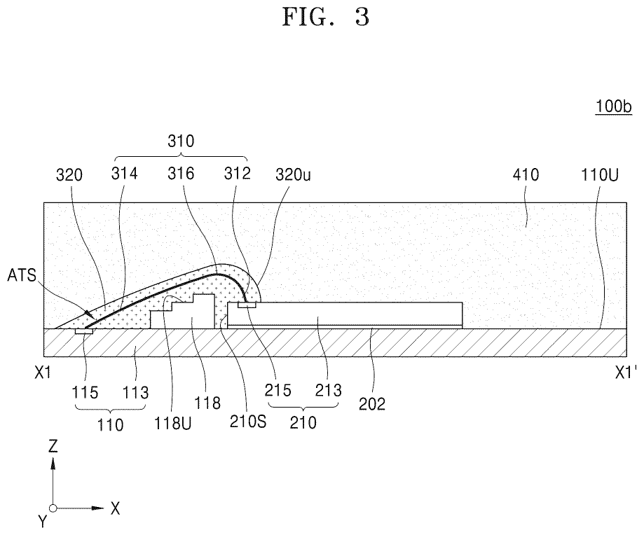

FIG. 3 is a cross-sectional view of a semiconductor package 100b according to some embodiments, and is a portion corresponding to the cross-sectional view taken along line X1-X1′ of FIG. 1. A difference between FIG. 3 and FIG. 2 is whether the upper surface 118U of the first dam structure 118 has a staircase structure. In FIG. 3, reference numerals that are the same as those in FIGS. 1A, 1B, and 2 denote elements that are the same as those in FIGS. 1A, 1B, and 2. Therefore, to the extent that details are not described, it may be assumed that the elements are at least similar to corresponding elements described elsewhere in the specification.

Referring to FIG. 3, the upper surface 118U of the first dam structure 118 extends in a direction away from the side wall 210S of the semiconductor chip 210 and a vertical level of the first dam structure 118 may decrease in a stepwise manner. In some embodiments, the upper surface 118U of the first dam structure 118 may include portions parallel to the package substrate 110 and portions perpendicular to the package substrate 110 and has a relatively large surface area, such that a sufficient contact area with the non-conductive filler 320 may be secured.

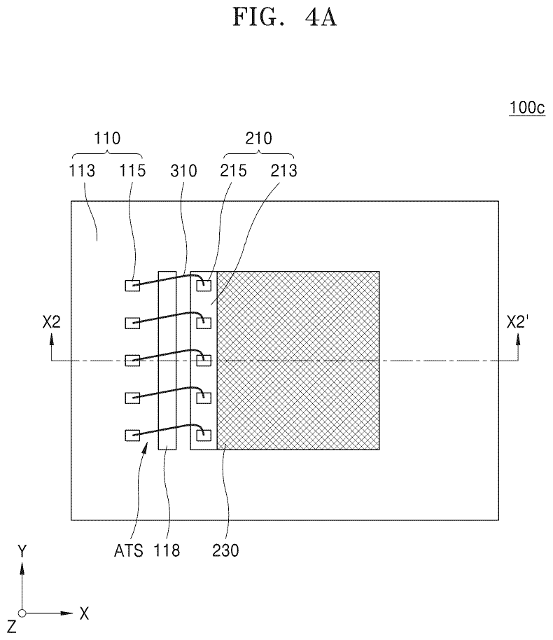

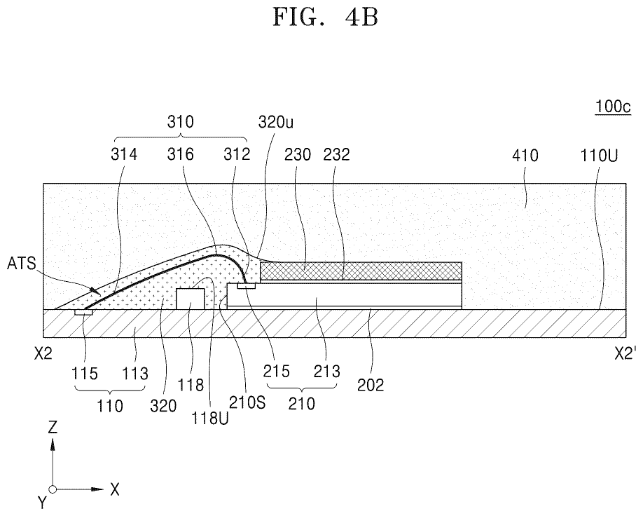

FIG. 4A is a plan view of a semiconductor package 100c according to some embodiments. FIG. 4B is a cross-sectional view of the semiconductor package 100c taken along line X2-X2′ of FIG. 4A. A difference between FIGS. 4A and 4B and FIGS. 1A and 1B is whether the semiconductor package 100c further includes a second dam structure 230 disposed on the semiconductor chip 210. In FIGS. 4A and 4B, reference numerals that are the same as those in FIGS. 1A and 1B denote members that are the same as those in FIGS. 1A and 1B. Therefore, to the extent that details are not described, it may be assumed that the elements are at least similar to corresponding elements described elsewhere in the specification.

According to embodiments, the semiconductor package 100c may further include the second dam structure 230 disposed on an upper surface of the semiconductor chip 210. The second dam structure 230 may be attached onto an upper surface of the semiconductor chip 210 via, for example, a die adhesive film 232 arranged between the second dam structure 230 and the semiconductor chip 210.

The second dam structure 230 might not cover the plurality of bonding pads 215. For example, the second dam structure 230 may cover an upper surface of the semiconductor chip 210 and expose the plurality of bonding pads 215.

The second dam structure 230 may be arranged apart from the plurality of bonding wires 310, on the semiconductor chip 210. The non-conductive filler 320 may include a portion arranged between the semiconductor chip 210 and the plurality of bonding wires 310. In some embodiments, the non-conductive filler 320 may be in contact with at least a portion of a side wall 230S of the second dam structure 230. The second dam structure 230 may be spaced apart from the plurality of bonding pads 215 and arranged adjacent to the plurality of bonding wires 310 to prevent an NCP for forming the non-conductive filler 320 from dispersing when the NCP is applied. In addition, the NCP has interfacial tension when in contact with the side wall 230S of the second dam structure 230, and thus may more easily cover the first portion 312 and a peak of the third portion 316 of the plurality of bonding wires 310 which is arranged at a higher vertical level than an upper surface of the semiconductor chip 210.

A first portion of the upper surface 320U of the non-conductive filler 320, the first portion vertically overlapping the third portion 316 of the plurality of bonding wires 310, may have a curvature corresponding to a first curvature at a peak of the plurality of bonding wires 310. In some embodiments, because the non-conductive filler 320 covers the side wall 230S of the second dam structure 230, the inclination of a second portion of the upper surface 320U of the non-conductive filler 320, the second portion vertically overlapping the first portion 312 of the plurality of bonding wires 310, may be less than the inclination of the second portion of the upper surface 320U of the non-conductive filler 320 in the semiconductor package 100 described with reference to FIGS. 1A and 1B. In this case, the first portion of the upper surface 320U of the non-conductive filler 320 may have a curvature that is less than the first curvature.

An upper surface of the second dam structure 230 may be arranged at a lower vertical level than a peak of the plurality of bonding wires 310. In this case, the non-conductive filler 320 may be arranged between the plurality of bonding wires 310 and the side wall 230S of the second dam structure 230 and may completely cover the side wall 230S of the second dam structure 230. In some embodiments, the non-conductive filler 320 may cover an edge portion of an upper surface of the second dam structure 230. In some embodiments, an upper surface of the second dam structure 230 may be arranged at a higher vertical level than a peak of the plurality of bonding wires 310.

The mold layer 410 may at least partially cover the upper surface 110U of the package substrate 110 and surround the non-conductive filler 320, the semiconductor chip 210, and the second dam structure 230.

The second dam structure 230 may include a material having a higher thermal conductivity than the semiconductor chip 210 and the mold layer 410. For example, the second dam structure 230 may prevent the NCP from flowing during formation of the non-conductive filler 320, and may radiate heat from the semiconductor chip 210 upward during operation of the semiconductor package 100c. In some embodiments, the second dam structure 230 may include a metal, such as copper (Cu), nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), etc., or an alloy thereof. In some embodiments, the second dam structure 230 may instead include ceramic or graphite including zirconium oxide (ZrO₂), aluminum oxide (Al₂O₃), silicon carbide (SiC), and silicon nitride (Si₃N₄), but is not limited to the aforementioned examples. The thermal conductivity of the second dam structure 230 may be range from about 10 W/mK to about 450 W/mK. The second dam structure 230 as used herein may be referred to as a heat dissipation structure.

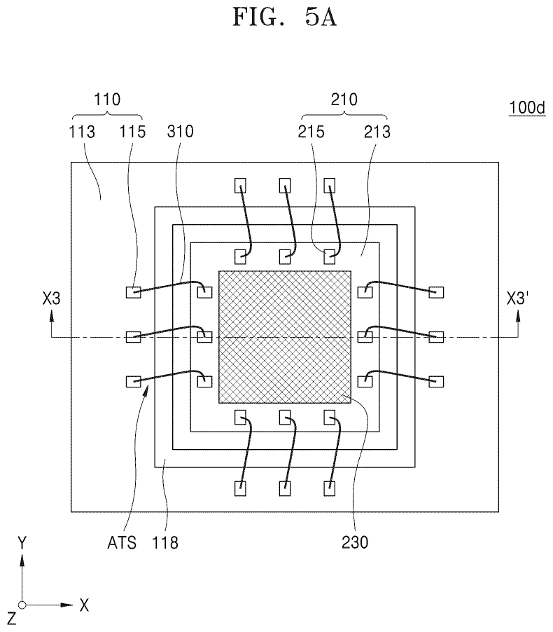

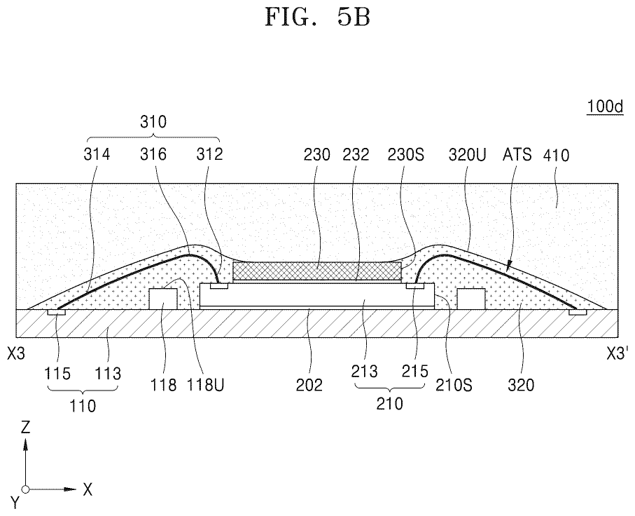

FIG. 5A is a plan view of a semiconductor package 100d according to some embodiments. FIG. 5B is a cross-sectional view of the semiconductor package 100d taken along line X3-X3′ of FIG. 5A. A difference between FIGS. 5A and 5B and FIGS. 4A and 4B is whether the plurality of bonding wires 310 of the semiconductor package 100d are arranged along a perimeter of the semiconductor chip 210. In FIGS. 5A and 5B, reference numerals that are the same as those in FIGS. 1A, 1B, 4A, and 4B denote elements that are the same as those in FIGS. 1A, 1B, 4A. Therefore, to the extent that details are not described, it may be assumed that the elements are at least similar to corresponding elements described elsewhere in the specification.

According to embodiments, the plurality of connection pads 115 may be disposed on an upper surface 110U of the package substrate 110 along a perimeter of the semiconductor chip 210, and in a plan view, may be arranged to surround the semiconductor chip 210. In some embodiments, the plurality of connection pads 115 may be arranged to be parallel to each of four sides of the semiconductor chip 210. According to embodiments, the plurality of bonding pads 215 may be disposed on an upper surface of the semiconductor chip 210 along a perimeter of the semiconductor chip 210. In some embodiments, the plurality of bonding pads 215 may be arranged to be parallel to each of four sides of the semiconductor chip 210.

According to embodiments, the first dam structure 118 may be spaced apart from the side wall 210S of the semiconductor chip 210, and in a plan view, may be arranged to surround the semiconductor chip 210. The first dam structure 118 may be arranged between the plurality of connection pads 115 and the semiconductor chip 210. The first dam structure 118 may have a closed loop shape, but is not necessarily limited thereto. For example, unlike shown in FIG. 5A, the first dam structure 118 may include four rod-shaped segments parallel to respective side walls of the semiconductor chip 210, and the segments may be spaced apart from each other.

According to embodiments, the plurality of bonding wires 310 may be disposed on the first dam structure 118 along a perimeter of the semiconductor chip 210. According to embodiments, the first dam structure 118 vertically overlaps the plurality of bonding wires 310, and may be disposed under the plurality of bonding wires 310 to pass the arch tunnel structure ATS including the plurality of bonding wires 310.

According to embodiments, the second dam structure 230 may be disposed on the semiconductor chip 210, and in a plan view, the second dam structure 230 may be surrounded by the plurality of bonding pads 215. For example, the second dam structure 230 may be disposed at a center portion of an upper surface of the semiconductor chip 210, and an outer boundary of the second dam structure 230 may be arranged to be spaced apart from the plurality of bonding pads 215, which are arranged along an edge of the second dam structure 230, toward the center portion.

According to embodiments, in a plan view, the non-conductive filler 320 may be arranged to surround an outer boundary of the second dam structure 230. According to embodiments, the non-conductive filler 320 may be in contact with at least a portion of the side wall 230S of the second dam structure 230, and may cover the plurality of bonding wires 310, the first dam structure 118, the plurality of connection pads 115, and the plurality of bonding pads 215. According to embodiments, the plurality of bonding wires 310 and the side wall 210S and an edge portion of an upper surface of the semiconductor chip 210 may be surrounded by the non-conductive filler 320, and a center portion excluding the edge portion of the upper surface of the semiconductor chip 210 may be covered with the second dam structure 230. For example, a portion of the upper surface of the semiconductor chip 210 may be covered with the second dam structure 230, and a remaining portion of the upper surface of the semiconductor chip 210 may be covered with the non-conductive filler 320. According to embodiments, the mold layer 410 may cover an upper surface 110U of the package substrate 110 and surround the non-conductive filler 320 and the second dam structure 230.

Hereinafter, a method of manufacturing the semiconductor package 100d, according to embodiments, is described using a specific example.

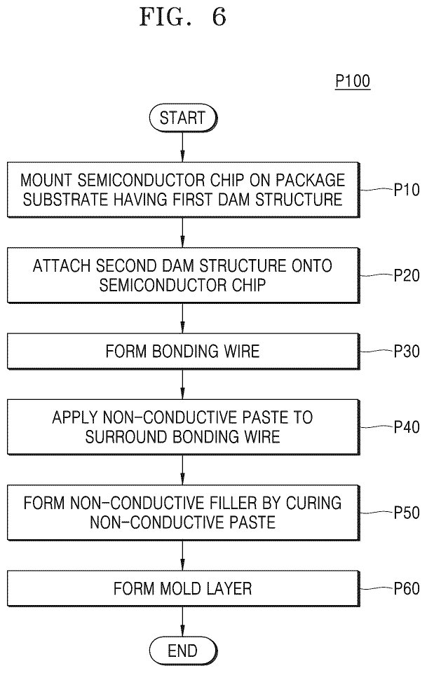

FIG. 6 is a flow chart for describing a method P100 of manufacturing the semiconductor package 100d, according to embodiments. FIGS. 7A to 7E are cross-sectional views illustrating the method P100 of manufacturing the semiconductor package 100d, according to embodiments. In detail, FIGS. 7A to 7E are each a cross-sectional view of a portion corresponding to a cross-section taken along line X3-X3′ of FIG. 5A. In FIGS. 7A to 7E, reference numerals that are the same as those in FIGS. 1A, 1B, 4A, 4B, 5A, and 5B denote members that are the same as those in FIGS. 1A, 1B, 4A, 4B, 5A, and 5B. Therefore, to the extent that details are not described, it may be assumed that the elements are at least similar to corresponding elements described elsewhere in the specification.

Referring to FIGS. 6 and 7A together, the semiconductor chip 210 may be mounted on the package substrate 110 having the first dam structure 118 on an upper surface thereof (operation P10).

According to embodiments, the first dam structure 118 may be formed via a photoresist process during a process of manufacturing the package substrate 110, and may extend in an arrangement direction of the plurality of connection pads 115. For example, the first dam structure 118 may include the same material as that of the base layer 113.

According to embodiments, on the package substrate 110, the semiconductor chip 210 may be attached onto one side of the first dam structure 118. The semiconductor chip 210 may be arranged such that the inactive surface of the semiconductor substrate 213 faces downward, that is, facing the upper surface 110U of the package substrate 110. The plurality of bonding pads 215 may be disposed on an upper surface of the semiconductor substrate 213 and exposed to an upper surface of the semiconductor chip 210.

In some embodiments, the first dam structure 118 may be formed by a different process from the package substrate 110, and may include a different material from that of the base layer 113. After the first dam structure 118 may be attached onto the package substrate 110 via a separate die adhesive film, the semiconductor chip 210 may be attached onto one side of the first dam structure 118. Alternatively, after the semiconductor chip 210 is attached onto one side of the plurality of connection pads 115, the first dam structure 118 may be attached between the plurality of connection pads 115 and the semiconductor chip 210.

Referring to FIGS. 6 and 7B together, the second dam structure 230 may be attached onto an upper surface of the semiconductor chip 210 (operation P20). The second dam structure 230 may be attached onto the upper surface of the semiconductor chip 210 via the die adhesive film 232 covering a bottom surface of the second dam structure 230. According to embodiments, the second dam structure 230 may be arranged at a center of an upper surface of the semiconductor chip 210, and in a plan view, may be arranged to be surrounded by the plurality of bonding pads 215.

Referring to FIGS. 6 and 7C together, the plurality of bonding wires 310 may be formed that respectively connect the plurality of connection pads 115 to the plurality of bonding pads 215 (operation P30). According to embodiments, each of the plurality of bonding wires 310 may be formed to have an arc shape having a curvature. Accordingly, each of the plurality of bonding wires 310 may have a peak with a maximum vertical level, and may have one end, which is in contact with and connected to each bonding pad 215, and the other end, which is in contact with and connected to each connection pad 115. In some embodiments, a wire lower space WUS may be formed below the arch tunnel structure ATS, encompassing the plurality of bonding wires 310. The wire lower space WUS may be delineated by the plurality of bonding wires 310, a portion of the upper surface 110U of the package substrate 110, an upper surface and side wall of the first dam structure 118, a portion of an upper surface of the semiconductor chip 210, and the side wall 210S of the semiconductor chip 210.

According to embodiments, each of the plurality of bonding wires 310 may be individually formed, and may be formed via methods, such as thermo compression connection, ultra sonic connection, and thermal sonic connection that is a combination of the thermal compression connection and the ultra sonic connection.

Referring to FIGS. 6 and 7D, a NCP may be applied on the plurality of bonding wires 310 (operation P40). According to embodiments, the NCP may surround the plurality of bonding wires 310 and may flows into a space between the plurality of bonding wires 310, for example, a space between the plurality of bonding wires 310 spaced apart from each other in a horizontal direction, to fill the wire lower space WUS (see FIG. 7C). The NCP may be dispersed to cover the first dam structure 118, the plurality of connection pads 115, the plurality of bonding pads 215, the side wall 210S of the semiconductor chip 210, and the side wall 230S of the second dam structure 230, and may fill a space between the first dam structure 118 and the side wall 210S of the semiconductor chip 210 and a space between the plurality of bonding wires 310 and the side wall 230S of the second dam structure 230.

In some embodiments, the NCP may be a fluid and flow with tension at an interface with a component which the NCP is in contact with. According to the method P100 of manufacturing the semiconductor package 100d, the first dam structure 118 may be disposed under the plurality of bonding wires 310 to prevent the NCP from dispersing and may serve as a scaffold such that the NCP surrounds the plurality of bonding wires 310. In addition, the second dam structure 230 may be arranged such that the side wall 230S is adjacent to the first portion 312 of the plurality of bonding wires 310, and prevents the NCP from dispersing, such that the NCP may stably surround the third portion 316 of the plurality of bonding wires 310 including a peak.

In some embodiments, the NCP may be applied in an extension direction of each of the plurality of bonding wires 310 (for example, in a direction from each connection pad 115 toward each bonding pad 215). For example, a nozzle which discharges the NCP may move on the plurality of bonding wires 310 in the extension direction of each bonding wire 310 and apply the NCP on the plurality of bonding wires 310. In some embodiments, the NCP may be applied along the arrangement direction of the plurality of bonding wires 310 (for example, an extension direction of the first dam structure 118). In some embodiments, the NCP may be applied in a diagonal direction with respect to the arrangement direction and extension direction of the plurality of bonding wires 310.

Afterwards, a resulting product obtained after applying the NCP may be cured to form the non-conductive filler 320 (operation P50). According to embodiments, operation P50 for curing the NCP may include baking the resulting product in an oven at a temperature of about 100° C. to about 300° C.

Referring to FIGS. 6 and 7E, the resulting product of FIG. 7D is put into a mold device 510 having therein a processing space CS, and the mold layer 410 is formed that covers an upper surface 110U of the package substrate 110 and surrounds the non-conductive filler 320 and the second dam structure 230 (operation P60).

Referring to FIG. 7E, the mold device 510 may be configured to isolate the processing space CS from the outside. The mold device 510 may include: an inlet 502 through which a fluidic mold material 402 is introduced; and an outlet 504 through which a process gas discharged in a mold process is discharged. In some embodiments, the mold device 510 may be configured such that the inlet 502 and the outlet 504 are closed to maintain the processing space CS in a vacuum while a mold process is performed.

In some embodiments, the fluidic mold material 402 may be formed by applying heat and pressure to a granular epoxy mold compound. The fluidic mold material 402 may be introduced through the inlet 502 and flow through the processing space CS. In FIG. 7E, a flow direction MF of the fluidic mold material 402 is indicated by an arrow. According to the method P100 of manufacturing the semiconductor package, according to embodiments, the plurality of bonding wires 310 are surrounded and protected by the non-conductive filler 320, and thus may prevent a problem in which the plurality of bonding wires 310 are separated or swept, resulting in a short circuit, despite a pressure caused by the flow of the fluidic mold material 402.

In some embodiments, after the fluidic mold material 402 is injected to fill all of the processing space CS of the mold device 510, the fluidic mold material 402 may be cured to form the mold layer 410. Referring to FIGS. 7E and 5B together, the mold layer 410 may have a side surface and an upper surface which form a right angle. A marking pattern including information of the semiconductor chip 210, for example, a barcode, QR code, number, letter, symbol, etc., may be formed on the side surface and/or upper surface of the mold layer 410.

While the inventive concept has been particularly shown and described with reference to embodiments thereof, it will be understood that various changes in form and details may be made therein without departing from the spirit and scope of the following claims.

What is claimed is:

1. A semiconductor package, comprising:
a package substrate comprising a base layer and a connection pad disposed on an upper surface of the base layer;
a semiconductor chip disposed on the package substrate and the semiconductor chip comprises a semiconductor substrate and a bonding pad disposed on an upper surface of the semiconductor substrate;
a bonding wire in contact with the connection pad and the bonding pad;
a first dam structure disposed on the package substrate and arranged between the connection pad and the bonding pad;
a non-conductive filler disposed on the package substrate surrounding the first dam structure and the bonding wire; and
a mold layer disposed on the package substrate covering a portion of an upper surface of the package substrate and surrounding the semiconductor chip and the non-conductive filler.

2. The semiconductor package of claim 1, wherein the bonding wire has a curvature, and comprises:
a first portion in contact with the bonding pad;
a second portion in contact with the connection pad; and
a third portion disposed between the first portion and the second portion, the third portion having a peak with a maximum vertical level,
wherein an upper surface of the non-conductive filler has a curvature corresponding to the curvature of the bonding wire.

3. The semiconductor package of claim 1, wherein the first dam structure is spaced apart from a side wall of the semiconductor chip.

4. The semiconductor package of claim 3, wherein the non-conductive filler comprises a portion arranged between the side wall of the semiconductor chip and the first dam structure.

5. The semiconductor package of claim 1, wherein the non-conductive filler comprises a different material from that of the mold layer.

6. The semiconductor package of claim 1, wherein the non-conductive filler comprises a first silica filler,
wherein the mold layer comprises a second silica filler, and
wherein a size of the first silica filler is less than a size of the second silica filler.

7. The semiconductor package of claim 1, wherein an upper surface of the first dam structure extends with a downward slope in a direction away from a side wall of the semiconductor chip.

8. The semiconductor package of claim 1, wherein the first dam structure has a staircase structure in which a vertical level of an upper surface of the first dam structure gradually decreases in a direction away from the semiconductor chip.

9. The semiconductor package of claim 1, further comprising a second dam structure arranged apart from the bonding pad and disposed on the semiconductor chip,
wherein the non-conductive filler covers a side wall of the second dam structure.

10. The semiconductor package of claim 9, wherein the second dam structure comprises a material with a higher thermal conductivity than the mold layer.

11. A semiconductor package, comprising:
a package substrate comprising a base layer and a plurality of connection pads disposed on an upper surface of the base layer;
a semiconductor chip disposed on the package substrate and spaced apart from the plurality of connection pads, the semiconductor chip comprises a semiconductor substrate and a plurality of bonding pads disposed on an upper surface of the semiconductor substrate;
a heat dissipation structure spaced apart from the plurality of bonding pads and disposed on an upper surface of the semiconductor chip;
a plurality of bonding wires electrically connecting the plurality of connection pads to the plurality of bonding pads, respectively;
a non-conductive filler at least partially surrounding the plurality of bonding wires, filling a lower space of the plurality of bonding wires, and covering a side wall of the heat dissipation structure; and
a mold layer disposed on the package substrate surrounding the non-conductive filler, the heat dissipation structure, and the semiconductor chip.

12. The semiconductor package of claim 11, further comprising, a first dam structure disposed on the package substrate in a lower space of the plurality of bonding wires, the first dam structure is spaced apart from the semiconductor chip.

13. The semiconductor package of claim 12, wherein the plurality of connection pads are arranged along a perimeter of the package substrate in a first horizontal direction,
wherein the plurality of bonding pads are arranged along the perimeter of the package substrate in the first horizontal direction, and
wherein the first dam structure extends between the plurality of connection pads and the plurality of bonding pads in the first horizontal direction.

14. The semiconductor package of claim 11, wherein each of the plurality of bonding wires has a curvature, and comprises:
a first portion electrically connected to each of the plurality of bonding pads;
a second portion electrically connected to each of the plurality of connection pads; and
a third portion disposed between the first portion and the second portion,
wherein the third portion has a peak with a maximum vertical level; and
wherein an upper surface of the non-conductive filler with a curvature corresponding to the curvature of each of the plurality of bonding wires.

15. The semiconductor package of claim 11, wherein the non-conductive filler comprises a different material from that of the mold layer.

16. The semiconductor package of claim 11, wherein the non-conductive filler comprises a first silica filler,
wherein the mold layer comprises a second silica filler, and
wherein a size of the first silica filler is less than a size of the second silica filler.

17. A semiconductor package, comprising:
a package substrate comprising a base layer and a plurality of connection pads disposed on an upper surface of the base layer;
a semiconductor chip at least partially surrounded by the plurality of connection pads, on the package substrate, the semiconductor chip comprises a semiconductor substrate and a plurality of bonding pads arranged on an upper surface of the semiconductor substrate along a perimeter of the semiconductor chip;
a first dam structure spaced apart from the semiconductor chip, on the package substrate, and extending between the plurality of connection pads and the semiconductor chip along the perimeter of the semiconductor chip;
a second dam structure disposed on the semiconductor chip and covering a portion of an upper surface of the semiconductor chip and exposing the plurality of bonding pads;
a plurality of bonding wires electrically connecting the plurality of connection pads to the plurality of bonding pads;
a non-conductive filler disposed on the package substrate and at least partially surrounding the plurality of bonding wires and the first dam structure and covering at least a portion of a side wall of the second dam structure; and
a mold layer disposed on the package substrate covering the non-conductive filler and the second dam structure.

18. The semiconductor package of claim 17, wherein each of the plurality of bonding wires has a curvature, and
wherein an upper surface of the non-conductive filler has a curvature corresponding to the curvature of each of the plurality of bonding wires.

19. The semiconductor package of claim 17, wherein an upper surface of the first dam structure extends with a downward slope in a direction away from a side wall of the semiconductor chip.

20. The semiconductor package of claim 17, wherein the first dam structure has a staircase structure in which a vertical level of an upper surface of the first dam structure gradually decreases in a direction away from the semiconductor chip.
